(19) United States
(12) Patent Application Publication
(10) Pub. No.: US 2023/0116155 A1
(43) Pub. Date: Apr. 13, 2023

(54) SEMICONDUCTOR STRUCTURE AND METHOD FOR FORMING SAME

(71) Applicant: CHANGXIN MEMORY TECHNOLOGIES, INC., Hefei City (CN)

(72) Inventors: Yexiao YU, Hefei (CN); Zhongming LIU, Hefei (CN)

(21) Appl. No.: 17/849,987

(22) Filed: Jun. 27, 2022

Related U.S. Application Data
(63) Continuation of application No. PCT/CN2022/070599, filed on Jan. 6, 2022.

(30) Foreign Application Priority Data
Oct. 11, 2021 (CN) 202111181092.4

(51) Int. Cl. H01L 27/108

(52) U.S. Cl. CPC H01L 27/10894; H01L 27/10823; H01L 27/10897; H01L 27/10876; H01L 27/10885

(57) ABSTRACT

A method for forming a semiconductor structure includes: providing a semiconductor substrate including a memory area and a peripheral area; forming an insulating layer on a surface of the memory area, and forming a first metal layer on a surface of the peripheral area; etching the insulating layer and the memory area of the semiconductor substrate to form a plurality of bit line trenches arranged at intervals along a first direction and etched insulating layer, in which part of the bit line trench is located in the memory area of the semiconductor substrate, and the other part of the bit line trench is located in the etched insulating layer; forming a second metal layer on surfaces of the bit line trench, the memory area and the first metal layer; and etching the first metal layer and the second metal layer to form a semi-buried bit line structure and peripheral gate.

### CROSS-REFERENCE TO RELATED APPLICATIONS

This application is a U.S. continuation application of International Application No. PCT/CN2022/070599, filed on Jan. 6, 2022, which claims priority to Chinese Patent Application No. 202111181092.4, filed on Oct. 11, 2021. The disclosures of International Application No. PCT/CN2022/070599 and Chinese Patent Application No. 202111181092.4 are hereby incorporated by reference in their entireties.

### TECHNICAL FIELD

The disclosure relates to the technical field of semiconductors, and relates to but is not limited to a semiconductor structure and a method for forming the same.

### BACKGROUND

The development of dynamic memory pursues the requirements of high speed, high integration density, and low power consumption. With the miniaturization of semiconductor devices, especially in the manufacturing process of Dynamic Random Access Memory (DRAM) with critical size less than 20 nanometer (nm), the structural stability of bit lines directly determines the electrical performance of DRAM.

In related art, the bit lines of dynamic random access memory are located on the surface of active areas, and are prepared separately from peripheral gates (PG) in peripheral areas. Therefore, the preparation process thereof is complex and has a high cost. In addition, the structure of the bit lines formed in the related art is unstable, resulting in poor electrical performance of the dynamic random access memory.

### SUMMARY

In view of the above, embodiments of the disclosure provide a semiconductor structure and a method for forming the same.

In a first aspect, the embodiments of the disclosure provide a method for forming a semiconductor structure. The method includes the following operations.

A semiconductor substrate including a memory area and a peripheral area is provided. An insulating layer is formed on a surface of the memory area, and a first metal layer is formed on a surface of the peripheral area.

The insulating layer and the memory area of the semiconductor substrate are etched to form a plurality of bit line trenches arranged at intervals along a first direction and etched insulating layer. Part of the bit line trench is located in the memory area of the semiconductor substrate, and the other part of the bit line trench is located in the etched insulating layer.

A second metal layer is formed on a surface of the bit line trench, the surface of the memory area and a surface of the first metal layer.

The first metal layer and the second metal layer are etched to form a semi-buried bit line structure and a peripheral gate.

In a second aspect, the embodiments of the disclosure provide a semiconductor structure formed by the method for forming the semiconductor structure as mentioned above.

The semiconductor structure at least includes a semiconductor substrate including a memory area and a peripheral area; a etched insulating layer located on a surface of the memory area; a semi-buried bit line structure, in which a part of each semi-buried bit line structure is located in the memory area, and the other part of the semi-buried bit line structure is located in the etched insulating layer; and a peripheral gate located on the surface of the peripheral area.

### BRIEF DESCRIPTION OF THE DRAWINGS

In the drawings (which are not necessarily drawn to scale), similar reference numerals may describe similar components in different views. Similar reference symbols with different letter suffixes may denote different examples of similar components. The accompanying drawings generally illustrate the various embodiments discussed herein by way of examples but not limitation.

FIG. 1 schematically shows a flowchart of a method for forming a semiconductor structure provided by an embodiment of the disclosure.

FIGS. 2A to 2U schematically show structures during the method for forming a semiconductor structure provided by the embodiments of the disclosure.

FIG. 3 is a cross-sectional view along the X-axis direction of the semiconductor structure provided by the embodiments of the disclosure.

### DETAILED DESCRIPTION

Exemplary embodiments of the disclosure will be described in more detail below with reference to the accompanying drawings. Although the exemplary embodiments of the disclosure are shown in the accompanying drawings, it should be understood that the disclosure may be embodied in various forms and should not be limited by the specific embodiments set forth herein. On the contrary, these embodiments are provided to enable a more thorough understanding of the disclosure and to fully convey the scope of the disclosure to those skilled in the art.

In the following description, numerous specific details are given to provide a more thorough understanding of the disclosure. However, it will be apparent to those skilled in the art that the disclosure may be practiced without one or more of these details. In other examples, some technical features well known in the art are not described in order to avoid confusion with the disclosure. That is, not all features of the actual embodiments are described herein with not descripting well-known functions and structures in detail.

In the drawings, the dimension and relative dimension of a layer, an area, or an element may be exaggerated for clarity. Throughout, the same reference numerals denote the same elements.

It should be understood that when an element or layer is described as “on”, “adjacent to”, “connected to” or “coupled to” another element or layer, it may be directly on, adjacent to, connected to, or coupled to the other element or layer, or may exist intervening elements or layers. On the contrary, when an element is described as “directly on”, “directly adjacent to”, “directly connected to” or “directly coupled to” another element or layer, there is no intervening element or layer. It should be understood that when the terms “first”, “second”, “third” and so on are used to describe various elements, components, areas, layers, and/or portions, such elements, components, areas, layers, and/or portions should not be limited by such terms. These terms are used only to distinguish one element, component, area, layer, or portion from another element, component, area, layer, or portion. Thus, the first element, component, area, layer, or portion discussed below may be represented as the second element, component, area, layer, or portion without departing from the teachings of the disclosure. The discussion on the second element, component, area, layer, or portion does not imply that the first element, component, area, layer, or portion necessarily exists in the disclosure.

The terms used herein are intended to describe specific embodiments only and are not to be limitations of the disclosure. As used herein, singular forms of “a”, “an” and “said/the” are also intended to include the plural forms, unless the context clearly indicates otherwise. It should also be understood that the terms “composing” and/or “including”, when used in this specification, determine the presence of said features, integers, steps, operations, elements and/or components, but do not exclude the presence or addition of one or more other features, integers, steps, operations, elements, components and/or groups. As used herein, the term “and/or” includes any and all combinations of related listed items.

Based on the problems existing in the related art, the embodiments of the disclosure provide a semiconductor structure and a method for forming the same. In this disclosure, the method for forming the semiconductor structure includes: providing a semiconductor substrate including a memory area and a peripheral area; forming an insulating layer on a surface of the memory area and forming a first metal layer on a surface of the peripheral area; etching the insulating layer and the memory area of the semiconductor substrate to form a plurality of bit line trenches arranged at intervals along a first direction and the etched insulating layer, and forming a second metal layer on surfaces of the bit line trench, the memory area and the first metal layer; and etching the first metal layer and the second metal layer, to form a semi-buried bit line structure and peripheral gate. Regarding the semiconductor structure formed by the method for forming the semiconductor structure provided by the embodiments of the disclosure, the semi-buried bit line and the peripheral gate can be formed simultaneously, and the structure of the semi-buried bit line is stable, thereby greatly simplifying the preparation process of the semiconductor structure, reducing the preparation cost of the semiconductor structure, and improving the electrical performance of the semiconductor structure.

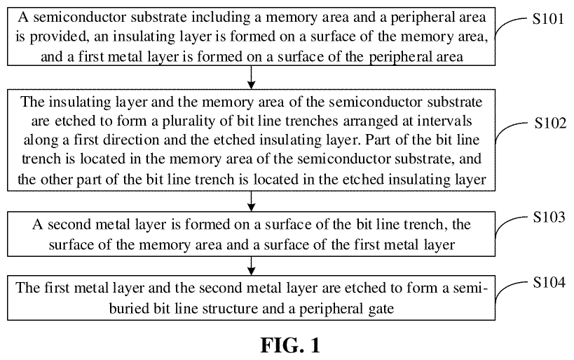

The embodiments of the disclosure provide a method for forming a semiconductor structure. FIG. 1 schematically shows a flowchart of a method for forming a semiconductor structure provided by an embodiment of the disclosure. As shown in FIG. 1, the method for forming a semiconductor structure includes the following operations.

At S101, a semiconductor substrate including a memory area and a peripheral area is provided. An insulating layer is formed on a surface of the memory area, and a first metal layer is formed on a surface of the peripheral area.

The semiconductor substrate may be a silicon substrate. The semiconductor substrate may further include other semiconductor elements such as germanium (Ge), or semiconductor compounds such as silicon carbide (SiC), gallium arsenide (GaAs), gallium phosphide (GaP), indium phosphide (InP), indium arsenide (InAs), or indium antimonide (InSb), or other semiconductor alloys such as silicon germanium (SiGe), arsenic gallium phosphide (GaAsP), indium aluminum arsenide (AlInAs), gallium aluminum arsenide (AlGaAs), indium gallium arsenide (GaInAs), indium gallium phosphide (GaInP) and/or indium gallium arsenide phosphide (GaInAsP) or combinations thereof.

In the embodiments of the disclosure, the memory area of the semiconductor substrate is used to form memory devices of the semiconductor device, such as storage capacitors. The peripheral area of the semiconductor substrate is used to form a peripheral control circuit of the semiconductor device. The insulating layer may be a material layer composed of any insulating material, such as a silicon nitride layer or a silicon oxynitride layer. The first metal layer may be a polysilicon layer, a doped silicon layer, or a silicide layer.

At S102, the insulating layer and the memory area of the semiconductor substrate are etched to form a plurality of bit line trenches arranged at intervals along a first direction and the etched insulating layer. Part of the bit line trench is located in the memory area of the semiconductor substrate, and the other part of the bit line trench is located in the etched insulating layer.

In the embodiments of the disclosure, the semiconductor substrate may include a top surface at a front face and a bottom surface at a back face opposite to the front face. A direction perpendicular to the top surface and the bottom surface of the semiconductor substrate is defined as a third direction, in the case of ignoring the flatness of the top surface and the bottom surface. A first direction and a second direction, which are intersecting each other (e.g. perpendicular to each other), are defined in the directions of the top surface and the bottom surface of the semiconductor substrate (that is, the plane where the semiconductor substrate is located). For example, an arrangement direction of the plurality of bit line trenches may be defined as the first direction, and a plane direction of the semiconductor substrate may be determined based on the first direction and second direction. Herein, the first direction, the second direction, and the third direction are pairwise perpendicular. In the embodiments of the disclosure, the first direction is defined as X-axis direction, the second direction is defined as Y-axis direction, and the third direction is defined as Z-axis direction.

In the embodiments of the disclosure, a part of the bit line trench is located in the memory area of the semiconductor substrate, and the other part of the bit line trench is located in the etched insulating layer. That is, the bit line trench in the embodiments of the disclosure is semi-buried in the semiconductor substrate.

At S103, a second metal layer is formed on a surface of the bit line trench, a surface of the memory area and a surface of the first metal layer.

The second metal layer may be composed of any conductive material, such as tungsten (W), cobalt (Co), copper (Cu), aluminum (Al), polysilicon, doped silicon, silicide, or any combination thereof.

At S104, the first metal layer and the second metal layer are etched to form a semi-buried bit line structure and a peripheral gate.

In the embodiments of the disclosure, part of the semi-buried bit line structure is located in the memory area of the semiconductor substrate, and the other part of the semi-buried bit line structure is located in the etched insulating layer. The peripheral gate is a structural device located in the peripheral area.

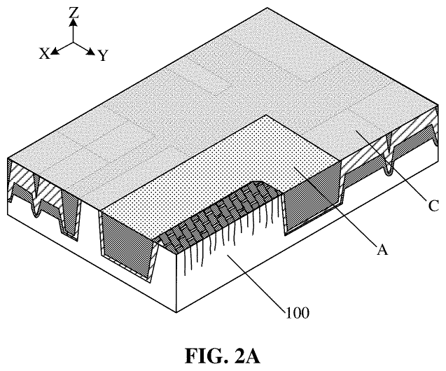

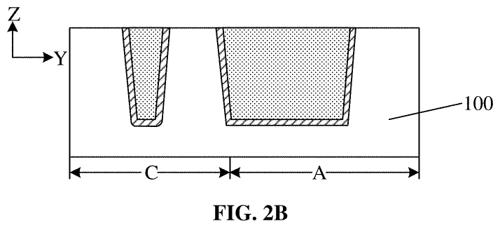

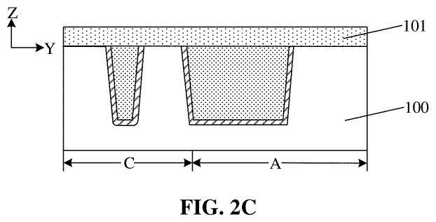

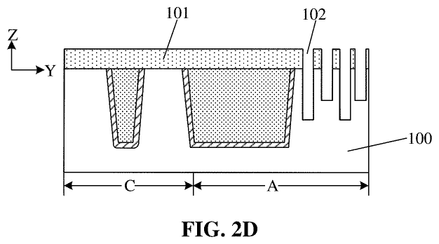

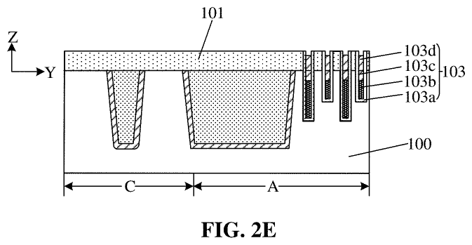

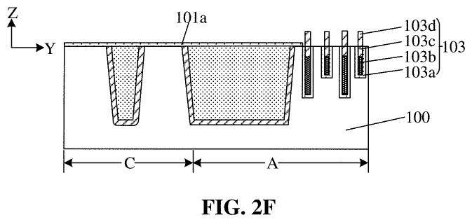

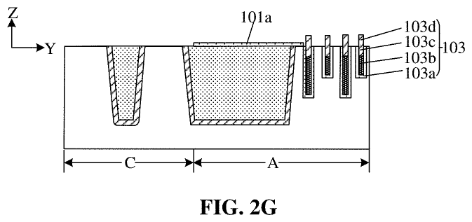

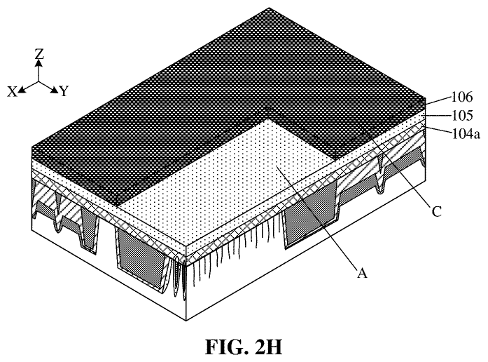

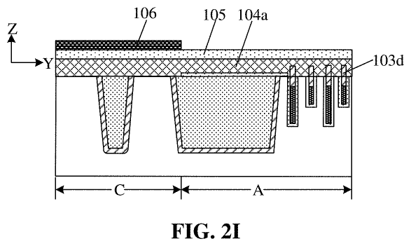

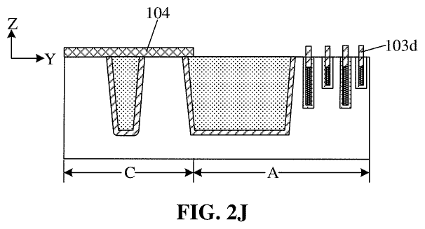

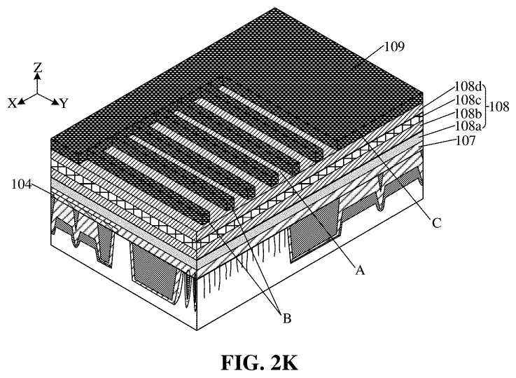

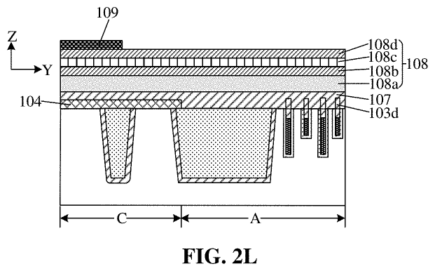

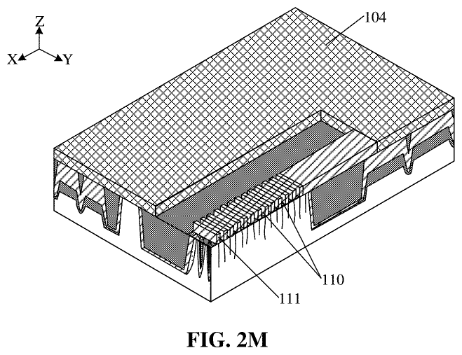

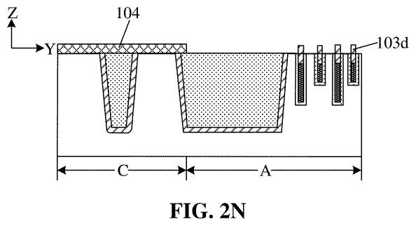

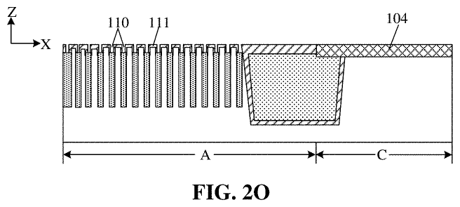

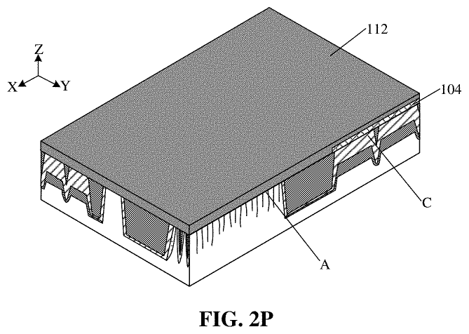

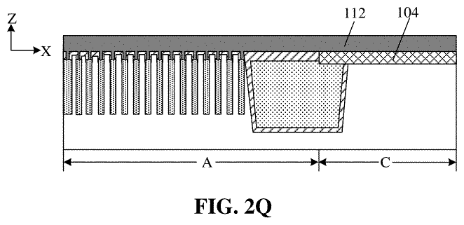

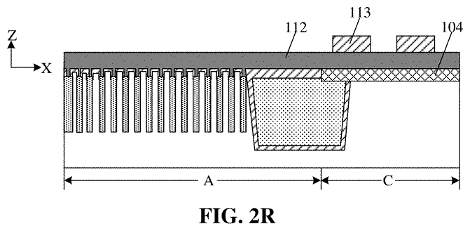

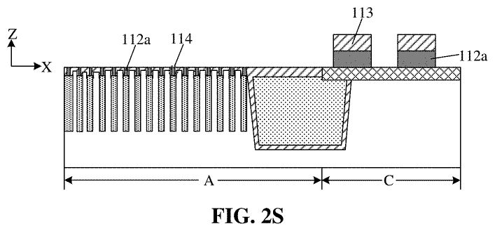

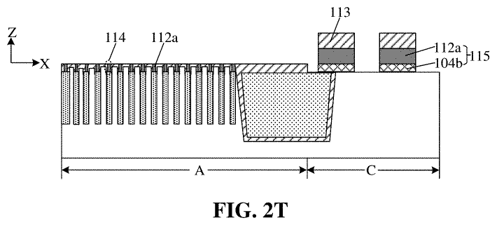

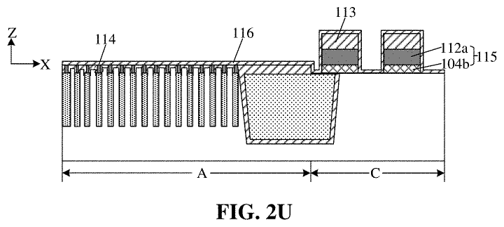

FIGS. 2A to 2U schematically show structures during the method for forming a semiconductor structure provided by the embodiments of the disclosure. The following provides a detailed description for the method for forming the semiconductor structure provided by the embodiments of the disclosure, with reference to FIGS. 2A to 2U.

First, referring to FIGS. 2A to 2J, S101 is performed. Specifically, a semiconductor substrate including a memory area and a peripheral area is provided, an insulating layer is formed on a surface of the memory area, and a first metal layer is formed on a surface of the peripheral area.

FIG. 2A shows a three-dimensional structural view of a semiconductor substrate provided by the embodiments of the disclosure, and FIG. 2B shows a cross-sectional view of a semiconductor substrate along the Y-axis direction. As shown in FIGS. 2A and 2B, the semiconductor substrate 100 includes a memory area A and a peripheral area C.

In some embodiments, the insulating layer located on the surface of the memory area includes first word line insulating layers, and a bit line insulating layer located between adjacent first word line insulating layers and covering the first word line insulating layers. The method for forming the semiconductor structure further includes an operation that a buried word line structure is formed in the memory area. Herein, the buried word line structure includes at least a first word line insulating layer, and the first word line insulating layer extends beyond a top surface of the peripheral area.

In some embodiments, the formation of the buried word line structure in a memory area includes the following operations.

At S11, a first isolation layer is formed on the surfaces of the memory area and the peripheral area.

The first isolation layer is a material layer formed of any insulating material. For example, the first isolation layer may be a silicon oxide layer or a silicon oxynitride layer. In the embodiments of the disclosure, the first isolation layer may be formed by any suitable deposition process, for example, a Chemical Vapor Deposition (CVD) process, a Physical Vapor Deposition (PVD) process, an Atomic Layer Deposition (ALD) process, a spin-coating process, or a coating process.

FIG. 2C shows a cross-sectional view along the Y-axis direction after forming the first isolation layer. As shown in FIG. 2C, the first isolation layer 101 is formed on the surfaces of the memory area A and the peripheral area C.

At S12, the first isolation layer on the surface of the memory area and the memory area are etched to form a plurality of word line trenches arranged at intervals along the second direction.

In the embodiments of the disclosure, a dry etching process, such as a plasma etching process, reactive ion etching process or ion milling process may be used to etch the first isolation layer on the surface of the memory area and the memory area, to form the word line trenches.

FIG. 2D shows a cross-sectional view along the Y-axis direction after forming the word line trenches. As shown in FIG. 2D, the first isolation layer 101 located on the surface of the memory area A and the semiconductor substrate corresponding to the memory area are etched along the Z-axis direction to form a plurality of word line trench 102 arranged at intervals in the Y-axis direction. As can be seen from FIG. 2D, part of the word line trench 102 is located in the semiconductor substrate of the memory area, and the other part of the word line trench 102 is located in the first isolation layer 101.

At S13, a buried word line structure is formed in the word line trench.

In some embodiments, S13 may include the following operations:

At S131, a gate oxide layer is formed on an inner wall of the word line trench.

At S132, a word line metal layer is formed in the word line trench where the gate oxide layer is formed.

At S133, a word line insulating layer is formed on a surface of the word line metal layer. The word line insulating layer includes a second word line insulating layer and a first word line insulating layer located on a surface of the second word line insulating layer.

In the embodiments of the disclosure, the gate oxide layer may be a silicon oxide layer. The metal material constituting the word line metal layer may be metal tungsten, titanium nitride or a combination thereof. The word line insulating layer may be a silicon nitride layer or a silicon oxynitride layer.

FIG. 2E shows a cross-sectional view along the Y-axis direction after forming the buried word line structure. As shown in FIG. 2E, a buried word line structure 103 is formed in the word line trench 102. The formation of the buried word line structure 103 includes the following operations. Firstly, a gate oxide layer 103a is formed on the inner wall of the word line trench 102. Secondly, a metal material is deposited in the word line trench where the gate oxide layer 103a is formed to form a word line metal layer 103b. Finally, a word line insulating layer is formed on a surface of the word line metal layer 103b. In the embodiments of the disclosure, the word line insulating layer includes a second word line insulating layer 103c and a first word line insulating layer 103d located on the surface of the second word line insulating layer 103c. The second word line insulating layer 103c is located inside the semiconductor substrate, and a first word line insulating layer 103d is located in the first isolation layer 101. That is, in the embodiments of the disclosure, the first word line insulating layer 103d extends beyond the surface of the semiconductor substrate.

In some embodiments, the top surface of the first word line insulating layer 103d extends the top surface of the peripheral area by 70 to 90 nanometers (nm). In the embodiments of the disclosure, the top surface of the first word line insulating layer is arranged beyond the top surface of the peripheral area, so that sufficient space can be provided for subsequent buried bit line.

In some embodiments, after forming the buried word line, the method for forming the semiconductor structure further includes the following operations.

At S14, part of the first isolation layer is removed from the peripheral area and the memory area to expose the first word line insulation layer.

At S15, after exposing the first word line insulating layer, the first isolation layer is removed from the remaining surface of the peripheral area to expose the surface of the peripheral area.

FIGS. 2F and 2G show cross-sectional views along the Y-axis direction after removing part of the first isolation layer provided by the embodiments of the disclosure. First, as shown in FIG. 2F, the first isolation layer is partially removed from the peripheral area C and the memory area A along the thickness direction to expose the first word line insulating layer 103d, and retain remaining first isolation layer 101a on the peripheral area C and part of the memory area A. Next, as shown in FIG. 2G, the remaining first isolation layer 101a on the peripheral area C is removed to expose the surface of the semiconductor substrate of the peripheral area C, and retain remaining first isolation layer 101a on part of the memory area A.

In some embodiments, the first metal layer on the surface of the peripheral region may be formed by the following operations.

At S16, a first initial metal layer, a first mask layer and a first photoresist layer are sequentially formed on surfaces of the peripheral area, the memory area, and the first word line insulating layer.

FIG. 2H shows a three-dimensional view of a structure after a first initial metal layer, a first mask layer and a first photoresist layer are formed. FIG. 2I shows a cross-sectional view along the Y-axis direction after the first initial metal layer, the first mask layer and the first photoresist layer are formed. As shown in FIGS. 2H and 2I, the first initial metal layer 104a, the first mask layer 105 and the first photoresist layer 106 are successively formed on the surfaces of the peripheral area C and the memory area A. In the embodiments of the disclosure, the first photoresist layer 106 has a first preset pattern, and the memory area A is exposed by the first preset pattern.

At S17, the first mask layer is etched through the first photoresist layer to transfer the first preset pattern to the first mask layer, obtaining a patterned first mask layer.

At S18, the first initial metal layer is etched through the patterned first mask layer to form the first metal layer.

FIG. 2J shows a cross-sectional view along the Y-axis direction after the first metal layer is formed. As shown in FIG. 2J, the first mask layer 105 and the first initial metal layer 104a are sequentially etched through the first photoresist layer 106, to form the first metal layer 104 located on the surface of the semiconductor substrate in the peripheral area C.

Continuing to refer to FIG. 2J, the method for forming the semiconductor structure further includes an operation that the first photoresist layer and the patterned first mask layer are removed after forming the first metal layer 104.

In the embodiments of the disclosure, the first photoresist layer and the patterned first mask layer may be removed by using a wet or dry etching technique.

In some embodiments, the formation of the bit line insulating layer located between the adjacent first word line insulating layers and covering the first word line insulating layers is illustrated with reference to S102.

Next, referring to FIGS. 2K to 2O, S102 is performed. Specifically, the insulating layer and the memory area of the semiconductor substrate are etched to form a plurality of bit line trenches arranged at intervals along the first direction and etched insulating layer.

Part of the bit line trench is located in the memory area of the semiconductor substrate, and the other part of the bit line trench is located in the etched insulating layer.

In some embodiments, S102 may be performed by the following operations.

At S1021, a bit line insulating layer, a bit line mask layer and a second photoresist layer are sequentially formed on the surfaces of the first metal layer, the memory area, and the first word line insulating layer. The second photoresist layer has a second preset pattern including a plurality of sub-patterns arranged in parallel along the first direction. Each sub-pattern is used to form one bit line trench.

In the embodiments of the disclosure, the bit line insulating layer may be a silicon oxide layer, a silicon nitride layer or a silicon oxynitride layer. The bit line mask layer may be composed of one hard mask layer or multiple hard mask layers.

FIG. 2K shows a three-dimensional structural view after the bit line insulating layer, the bit line mask layer, and the second photoresist layer are formed. FIG. 2L shows a cross-sectional view along the Y-axis direction after the bit line insulating layer, the bit line mask layer, and the second photoresist layer are formed. As shown in FIGS. 2K and 2L, the bit line insulating layer 107, the bit line mask layer 108, and the second photoresist layer 109 are sequentially formed on the surfaces of the first metal layer 104, the memory area A, and the first word line insulating layer 103d. In the embodiments of the disclosure, the bit line mask layer 108 includes an amorphous carbon layer (ACL) 108a, a first silicon oxynitride layer 108b, a Spin-On mask layer (SOH) 108c, and a second silicon oxynitride layer 108d stacked in sequence from bottom to top.

In the embodiments of the disclosure, the second photoresist layer 109 has the second preset pattern including a plurality of sub-patterns B arranged in parallel along the X-axis direction. Each sub-pattern B is used for forming one bit line trench.

It should be noted that, in the embodiments of the disclosure, the window for forming the bit line trench is large and extends to the peripheral area, because it is necessary to lead the bit line from the memory area to the peripheral area, so as to facilitate the access and lead-out of the bit line electrical signal.

At S1022, the bit line mask layer is etched through the second photoresist layer to transfer the sub-pattern to the bit line mask layer, obtaining a patterned bit line mask layer.

At S1023, the bit line insulating layer, the first word line insulating layer and the memory area are etched through the patterned bit line mask layer to form a bit line trench.

FIG. 2M shows a three-dimensional structural view after the bit line trench is formed, FIG. 2N shows a cross-sectional view along the Y-axis direction after the bit line trench is formed, and FIG. 2O shows a cross-sectional view along the X-axis direction after the bit line trench is formed. As shown in FIGS. 2M to 2O, the second silicon oxynitride layer 108d, the spin-coated hard mask layer 108c, the first silicon oxynitride layer 108b, the amorphous carbon layer 108a and the bit line insulating layer 107 are sequentially etched along the Z-axis direction through the second photoresist layer 109 to form a plurality of bit line trenches 110 arranged at intervals along the X-axis direction. It can be seen that part of the formed bit line trench 110 is located in the semiconductor substrate of the memory area A, and the other part of the bit line trench 110 is located in the etched insulating layer 111 (including the etched bit line insulating layer and the etched first word line insulating layer).

It should be noted that in the embodiments of the disclosure, the first word line insulating layer is partially etched along the height direction during the formation of the bit line trench.

Referring to FIGS. 2M to 2O, after forming the bit line trench, the second photoresist layer, the patterned bit line mask layer, and the bit line insulating layer on the peripheral region surface are removed.

Next, referring to FIGS. 2P and 2Q, S103 is performed. Specifically, a second metal layer is formed on the surfaces of the bit line trench, the memory area and the first metal layer.

The second metal layer may also be composed of any conductive material, such as tungsten, cobalt, copper, aluminum, titanium nitride, polysilicon, doped silicon, silicide, or any combination thereof.

In some embodiments, the first metal layer and the second metal layer may be the same or different. In the embodiments of the disclosure, the first metal layer is different from the second metal layer. For example, the first metal layer may be a polysilicon layer, while the second metal layer may be a metallic tungsten layer.

FIG. 2P shows a three-dimensional structural view after the second metal layer is formed, and FIG. 2Q shows a cross-sectional view along the X-axis direction after the second metal layer is formed. As shown in FIGS. 2P and 2Q, the second metal layer 112 is formed on the surfaces of the bit line trench, the memory area A and the first metal layer 104.

Next, referring to FIGS. 2R to 2T, S104 is performed. Specifically, the first metal layer and the second metal layer are etched to form a semi-buried bit line structure and a peripheral gate.

In some embodiments, S104 may include the following operations.

At S1041, a second mask layer is formed on the surface of the second metal layer in the peripheral area.

In the embodiments of the disclosure, the second mask layer is used for forming the peripheral gate, and the second mask layer may be a silicon nitride layer.

FIG. 2R shows a cross-sectional view along the X-axis direction after the second mask layer is formed. As shown in FIG. 2R, the second mask layer 113 is formed on the surface of the second metal layer 112 in the peripheral area.

At S1042, the second metal layer is etched through the second mask layer to form etched second metal layers. The etched second metal layer located in the bit line trench constitutes a semi-buried bit line structure.

FIG. 2S shows a cross-sectional view along the X-axis direction after the semi-buried bit line structure is formed. As shown in FIG. 2S, the second metal layer 112 is etched through the second mask layer 113 to form the etched second metal layer 112a. The etched second metal layer 112a in the bit line trench constitutes the semi-buried bit line structure 114.

In the embodiments of the disclosure, part of the formed buried bit line structure is located in the memory area A of the semiconductor substrate, and the other part is located in the insulating layer on the surface of the semiconductor substrate in the memory area, so that the semi-buried bit line structure can be formed.

At S1043, the first metal layer is etched through the etched second metal layer to form etched first metal layer. The etched first metal layer and the etched second metal layer located in the peripheral area together constitute a peripheral gate.

FIG. 2T shows a cross-sectional view along the X-axis direction after the peripheral gate is formed. As shown in FIG. 2T, the first metal layer 104 is etched through the etched second metal layer 112a to form the etched first metal layer 104b. The etched first metal layer 104b and the etched second metal layer 112a located in the peripheral area C together constitute the peripheral gate 115.

It should be noted that, in the embodiments of the disclosure, the etched second metal layer 112a located in the bit line trench would not be etched when the first metal layer is etched through the etched second metal layers to form the etched first metal layer, due to the etching load effect caused by the different pattern densities of the array area A and the peripheral area C.

In some embodiments, the method for forming the semiconductor structure further includes an operation that a second isolation layer is formed on surfaces of the peripheral area, the memory area, and the peripheral gate, after forming the semi-buried bit line structure and the peripheral gate.

FIG. 2U shows a cross-sectional view along the X-axis direction after the second isolation layer is formed. As shown in FIG. 2U, the second isolation layer 116 is formed on the surfaces of the peripheral area C, the memory area A, the semi-buried bit line structure 114, and the peripheral gate 115. In the embodiments of the disclosure, the second isolation layer 116 is used to isolate the semi-buried bit line structures 114 from other components of the semiconductor structure. The second isolation layer 116 is also used to isolate the peripheral gate 115 from other components of the semiconductor structure.

When forming a semiconductor structure by the method for forming a semiconductor structure provided by the embodiments of the disclosure, the semi-buried bit line and the peripheral gate can be formed simultaneously, and the structure of the semi-buried bit line is stable, thereby greatly simplifying the preparation process of the semiconductor structure, reducing the preparation cost of the semiconductor structure, and improving the electrical performance of the semiconductor structure.

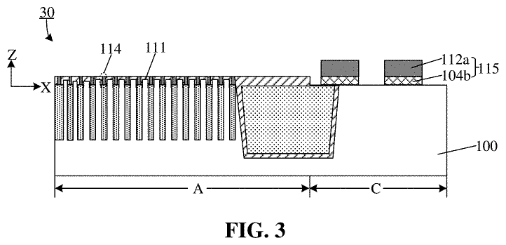

In addition, the embodiments of the disclosure also provide a semiconductor structure formed by the method for forming the semiconductor structure provided by the above embodiments. FIG. 3 shows a cross-sectional view along the X-axis direction of the semiconductor structure provided by the embodiments of the disclosure. As shown in FIG. 3, the semiconductor structure 30 includes a semiconductor substrate 100, the etched insulating layer 111, the semi-buried bit line structure 114, and the peripheral gate 115.

In the semiconductor structure, the semiconductor substrate 100 includes the memory area A and the peripheral area C. The memory area A is used for forming a memory device of the semiconductor device, such as storage capacitors. The peripheral area is used for forming a peripheral control circuit of the semiconductor device.

The etched insulating layer 111 is located on the surface of the memory area A. Part of the semi-buried bit line structure 114 is located in the memory area n A of the semiconductor substrate, and the other part of the semi-buried bit line structure 114 is located in the etched insulating layer 111.

The peripheral gate 115 is located on the surface of the peripheral area C, and is a functional device in the peripheral circuit.

In the embodiments of the disclosure, the etched insulating layer 111 includes at least etched first word line insulating layer. The semiconductor structure 30 also includes buried word line structure (not shown in the figure). The buried word line structure is located in the memory area A, and includes at least the etched first word line insulating layer. The etched first word line insulating layer exceeds the top surface of the peripheral area C by 70 to 90 nm.

In some embodiments, the semiconductor structure further includes a second isolation layer (not shown in the figure) on surfaces of the peripheral area C, the memory area A, the semi-buried bit line structure 114 and the peripheral gate 115. The second isolation layer is used to isolate the peripheral gates from other devices of the semiconductor structure, and also used to isolate the semi-buried bit line structure from other devices of the semiconductor structure.

It should be noted that, in the embodiments of the disclosure, through the method for forming the semiconductor structure provided by embodiments, the buried bit line structure and the peripheral gate can be prepared and formed simultaneously, thereby greatly simplifying the preparation process of the semiconductor structure.

Similar to the method for forming the semiconductor structure in the embodiments described above, regarding the semiconductor structure in the embodiments of the disclosure, technical features not disclosed in detail can be understood with reference to the above-mentioned embodiments, and the details will not be repeated here.

In the semiconductor structure provided by the embodiments of the disclosure, a part of the bit line is buried in the semiconductor substrate and the other part is buried in the insulating layer on the surface of the semiconductor substrate, so that the bit line structure can have a larger area, and thus the bit line has a stronger control ability.

In the several embodiments provided by the disclosure, it should be understood that the disclosed apparatus and methods may be implemented in a non-target manner The device embodiments described above is only schematic. For example, the division of the unit is only a logical function division, and there may be another division mode in actual implementation. For example, a plurality of units or components may be combined, or integrated into another system, or some features may be ignored or not executed. In addition, the components shown or discussed are coupled with each other, or directly coupled.

The units described as the above-mentioned separated components may or may not be physically separated. The components displayed as units may or may not be physical units. That is, they may be located in one place or distributed over multiple network units. Some or all of the units can be selected according to the actual needs to achieve the purpose of the embodiments.

The features in several methods or devices embodiments provided by the disclosure can be arbitrarily combined without conflict to obtain a new method embodiment or device embodiment.

The above descriptions are only some implementation modes of the embodiments of the disclosure, but the scope of protection of the embodiments of the disclosure is not limited thereto. Any variation or replacement readily figured out by a person skilled in the art within the technical scope disclosed in the disclosure shall fall within the scope of protection of the disclosure. Therefore, the scope of protection of the embodiments in the disclosure shall be subject to the scope of protection of the claims.

### INDUSTRIAL PRACTICALITY

A semiconductor structure and a method for forming a semiconductor structure are provided by the embodiments of the disclosure. The method for forming the semiconductor structure of the disclosure includes: providing a semiconductor substrate including a memory area and a peripheral area; forming an insulating layer on a surface of the memory area and forming a first metal layer on a surface of the peripheral area; etching the insulating layer and the memory area of the semiconductor substrate to form a plurality of bit line trenches arranged at intervals along a first direction and the etched insulating layer, and forming a second metal layer on surfaces of the bit line trench, the memory area and the first metal layer; and etching the first metal layer and the second metal layer, to form a semi-buried bit line structure and peripheral gate. Regarding the semiconductor structure formed by the method for forming the semiconductor structure provided by the embodiments of the disclosure, the semi-buried bit line and the peripheral gate can be formed simultaneously, and the structure of the semi-buried bit line is stable, thereby greatly simplifying the preparation process of the semiconductor structure, reducing the preparation cost of the semiconductor structure, and improving the electrical performance of the semiconductor structure.

1. A method for forming a semiconductor structure, comprising:
providing a semiconductor substrate comprising a memory area and a peripheral area, forming an insulating layer on a surface of the memory area, and forming a first metal layer on a surface of the peripheral area;
etching the insulating layer and the memory area of the semiconductor substrate to form a plurality of bit line trenches arranged at intervals along a first direction and etched insulating layer, wherein part of the bit line trench is located in the memory area of the semiconductor substrate, and other part of the bit line trench is located in the etched insulating layer;
forming a second metal layer on a surface of the bit line trench, the surface of the memory area, and a surface of the first metal layer; and
etching the first metal layer and the second metal layer to form a semi-buried bit line structure and a peripheral gate.

2. The method according to claim 1, wherein the insulating layer comprises first word line insulating layers, and a bit line insulating layer located between adjacent first word line insulating layers and covering the first word line insulating layers;
the method further comprises:
forming a buried word line structure in the memory area, wherein the buried word line structure at least comprises the first word line insulating layer, and the first word line insulating layer extends beyond a top surface of the peripheral area.

3. The method according to claim 2, wherein a top surface of the first word line insulating layer extends the top surface of the peripheral area by 70 to 90 nm.

4. The method according to claim 2, wherein the formation of the buried word line structure in the memory area comprises:
forming a first isolation layer on the surface of the memory area and the surface of the peripheral area;
etching the first isolation layer on the surface of the memory area and the memory area, to form a plurality of word line trenches arranged at intervals along a second direction perpendicular to the first direction; and
forming the buried word line structure in the word line trench.

5. The method according to claim 4, wherein the formation of the buried word line structure in the word line trench comprises:
forming a gate oxide layer on an inner wall of the word line trench;
forming a word line metal layer in the word line trench where the gate oxide layer is formed; and
forming a word line insulating layer on a surface of the word line metal layer, wherein the word line insulating layer comprises a second word line insulating layer and the first word line insulating layer located on the surface of the second word line insulating layer, wherein the first word line insulating layer is located in the first isolation layer.

6. The method according to claim 5, further comprising:
removing part of the first isolation layer in the peripheral area and the memory area to expose the first word line insulating layer, after the buried word line structure is formed.

7. The method according to claim 6, further comprising:
removing the first isolation layer remaining on the surface of the peripheral area to expose the surface of the peripheral area, after the first word line insulating layer is exposed.

8. The method according to claim 2, wherein the formation of the first metal layer consists of:
forming a first initial metal layer, a first mask layer and a first photoresist layer on the surface of the peripheral area, the surface of the memory area, and a surface of the first word line insulating layer in sequence, wherein the first photoresist layer has a first preset pattern for exposing the memory area;
etching the first mask layer through the first photoresist layer to transfer the first preset pattern to the first mask layer, obtaining a patterned first mask layer; and
etching the first initial metal layer by the patterned first mask layer to form the first metal layer.

9. The method according to claim 8, further comprising:
removing the first photoresist layer and the patterned first mask layer, after the first metal layer is formed.

10. The method according to claim 9, wherein the etching the insulating layer and the memory area to form the plurality of bit line trenches arranged at intervals along the first direction comprises:
forming a bit line insulating layer, a bit line mask layer and a second photoresist layer in sequence on a surface of the first metal layer, the surface of the memory area and the surface of the first word line insulating layer, wherein the second photoresist layer has a second preset pattern including a plurality of sub-patterns arranged in parallel along the first direction, and each of the sub-patterns is used for forming one bit line trench;
etching the bit line mask layer through the second photoresist layer to transfer the sub-pattern to the bit line mask layer, to obtain a patterned bit line mask layer; and
etching the bit line insulating layer, the first word line insulating layer and the memory area through the patterned bit line mask layer to form the bit line trench.

11. The method according to claim 10, further comprising:
removing the second photoresist layer, the patterned bit line mask layer, and the bit line insulating layer on the surface of the peripheral area, after the bit line trench is formed.

12. The method according to claim 11, wherein the etching the first metal layer and the second metal layer to form the semi-buried bit line structure and the peripheral gate comprises:
forming a second mask layer on a surface of the second metal layer in the peripheral area;
etching the second metal layer through the second mask layer to form etched second metal layer, wherein the etched second metal layer located in the bit line trench constitutes the semi-buried bit line structure; and
etching the first metal layer through the etched second metal layer to form etched first metal layer, wherein the etched first metal layer and the etched second metal layer located in the peripheral area together constitute the peripheral gate.

13. The method according to claim 1, further comprising:
forming a second isolation layer on the surface of the peripheral area, the surface of the memory area and a surface of the peripheral gate, after the semi-buried bit line structure and the peripheral gate are formed.

14. A semiconductor structure comprising:
a semiconductor substrate, comprising a memory area and a peripheral area;
an etched insulating layer, located on a surface of the memory area;
a semi-buried bit line structure, wherein part of the semi-buried bit line structure is located in the memory area, and other part of the semi-buried bit line structure is located in the etched insulating layer; and
a peripheral gate, located on a surface of the peripheral area.

15. The semiconductor structure according to claim 14, wherein the etched insulating layer comprises at least etched first word line insulating layer, and the semiconductor structure further comprises a buried word line structure;
the buried word line structure is located in the memory area, and comprises at least the etched first word line insulating layer, and the etched first word line insulating layer exceeds a top surface of the peripheral area.
